(19) United States
(12) Patent Application Publication
(10) Pub. No.: US 2015/0077124 A1
(43) Pub. Date: Mar. 19, 2015

(54) ASSEMBLED BATTERY MODULE AND DISCONNECTION DETECTING METHOD

(71) Applicant: Kabushiki Kaisha Toshiba, Tokyo (JP)

(72) Inventor: Atsuhisa SUZUKI, Kanagawa (JP)

(73) Assignee: KABUSHIKI KAISHA TOSHIBA, Tokyo (JP)

(21) Appl. No.: 14/191,256

(22) Filed: Feb. 26, 2014

(30) Foreign Application Priority Data
Sep. 17, 2013 (JP) 2013-192127

(51) Int. Cl. H02J 7/00; H01M 10/48; G01R 31/36

(52) U.S. Cl. CPC H02J 7/0036; G01R 31/3627; H01M 10/48; H02J 2007/0037
USPC 324/426; 429/90; 429/61

(57) ABSTRACT

An assembled battery module includes battery cells connected in series, resistors, a voltage measuring unit, failure detection switches, and a control unit. Each resistor is connected between a positive or negative electrode of the corresponding battery cell and a corresponding node for the positive or negative electrode. Each failure detection switch is connected between the two nodes corresponding to positive and negative electrodes of a battery cell to allow on-off switching between the two nodes. The control unit detects a disconnection between a positive or negative electrode of a battery cell to a corresponding node based on first and second voltages measured between two nodes, the first voltage being measured when one of the two failure detection switches connected to the corresponding node is switched from on to off and the second voltage being measured when the other failure detection switch is switched from on to off.

### CROSS-REFERENCE TO RELATED APPLICATION

This application is based upon and claims the benefit of priority from Japanese Patent Application No. 2013-192127, filed Sep. 17, 2013, the entire contents of which are incorporated herein by reference.

### FIELD

Embodiments described herein relate to an assembled battery module and a disconnection detecting method.

### BACKGROUND

An assembled battery (multiple in-series battery cells) which includes plural battery cells connected in series, is used as a power supply for electric automobiles, household electric products, and others. An assembled battery module includes the assembled battery, and a voltage monitoring circuit monitoring the voltage of each battery cell to ensure safe operation of the assembled battery. The voltage monitoring circuit includes a multiplexer capable of selecting any battery cell of the plural battery cells, a voltage measuring unit which measures voltages at both ends of the selected battery cell, and a cell balance unit which implements cell balance for equalizing energies of the respective battery cells by supplying current from an arbitrary battery cell to a resistor.

The route of the current supplied for the purpose of cell balance is disposed separately from the route of the voltage measurement. This arrangement allows measurement of the voltage of any battery cell in parallel with execution of cell balance for the corresponding battery cell.

When any wire connecting the corresponding battery cell and the multiplexer is disconnected in the assembled battery module having this structure, detection of the disconnection is needed. However, even in the case of disconnection of the wire, a voltage determined by the capacitor of the RC filter or a parasitic capacitance or the like generated on the wire between the position of disconnection and the multiplexer is supplied to the multiplexer. Therefore, a certain voltage is detected when the battery cell corresponding to the disconnected wire is selected by the multiplexer. In such a case, there is a possibility that the corresponding voltage that is detected is not greatly different from the voltages of the other normal battery cells. Accordingly, highly accurate detection of disconnection by detecting only the voltages of the respective battery cells, is difficult.

### DESCRIPTION OF THE DRAWINGS

FIG. 1 illustrates the general structure of an assembled battery module according to a first embodiment.

FIG. 2 illustrates the structure of a part of the assembled battery module for explaining a disconnection detecting method according to the first embodiment.

FIG. 3 shows voltages measured when the disconnection detecting method according to the first embodiment is executed in the normal condition.

FIG. 4 shows voltages measured when the disconnection detecting method according to the first embodiment is executed in the condition of disconnection.

FIG. 5 shows voltages measured when the disconnection detecting method according to the first embodiment is executed under the condition in which the voltage of a battery cell is 0V.

### DETAILED DESCRIPTION

In general, embodiments provide an assembled battery module and a disconnection detecting method capable of detecting disconnection with high accuracy.

According to one embodiment, an assembled battery module includes a plurality of battery cells connected in series, a plurality of resistors, a multiplexer, a voltage measuring unit, a plurality of failure detection switches, and a control unit. Each of the resistors is connected between a positive or negative electrode of a corresponding battery cell, and a corresponding node for the positive or negative electrode. The multiplexer is configured to select two nodes corresponding to the positive electrode and the negative electrode of any one of the battery cells. The voltage measuring unit is configured to measure the voltage between the two nodes selected by the multiplexer. Each of the failure detection switches is connected between two nodes corresponding to the positive electrode and the negative electrode of one of the battery cells to allow on-off switching between the two nodes. The control unit is configured to detect a disconnection between a positive or negative electrode of one of the battery cells and a corresponding node for the positive or negative electrode based on first and second voltages measured between the corresponding node and either a first node that is connected to the corresponding node through a first failure detection switch or a second node that is connected to the corresponding node through a second failure detection switch, the first voltage being measured when the second failure detection switch is switched from on to off and the second voltage being measured when the first failure detection switch is switched from on to off.

Exemplary embodiments are hereinafter described with reference to the drawings. These embodiments are presented by way of example only, and not intended to impose any limitations.

### First Embodiment

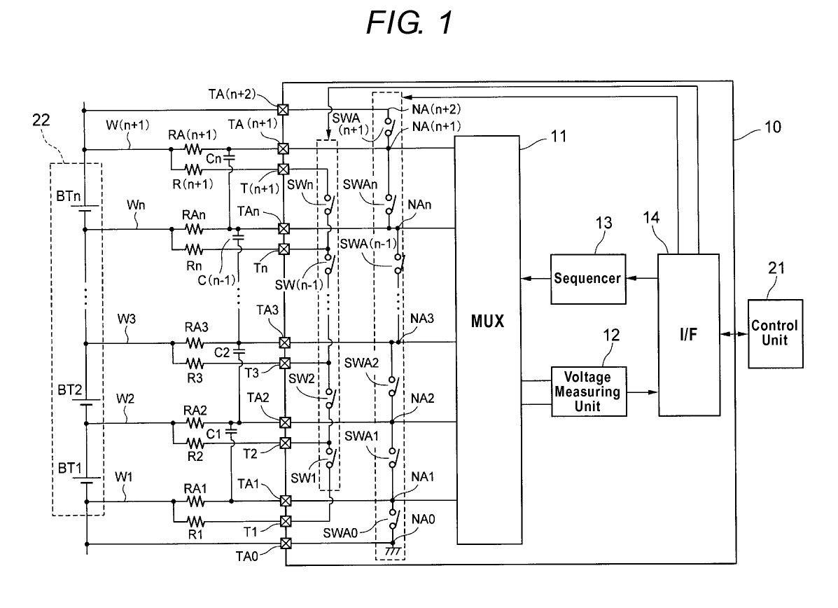

FIG. 1 illustrates the general structure of an assembled battery module according to a first embodiment. The assembled battery module includes n battery cells BT1 through BTn (where n is an integer greater than 1), n+1 cell balance resistors R1 through R(n+1), n+1 resistors RA1 through RA(n+1), n capacitors C1 through Cn, a battery monitoring circuit 10, and a control unit 21.

The battery cells BT1 through BTn are connected in series, and constitute an assembled battery (multiple in-series battery cells) 22. The battery cells BT1 through BTn are secondary batteries such as lithium ion batteries. The negative electrode of the lowermost battery cell BT1 and the positive electrode of the uppermost battery cell BTn are connected with a not-shown load or the like.

Each of the resistors RA1 through RA(n+1) has one end connected with the positive electrode or the negative electrode of the corresponding battery cell, and the other end connected with the corresponding one of the first input terminals TA1 through TA(n+1) of the voltage monitoring circuit 10. For example, the resistor RA1 has one end connected with the negative electrode of the battery cell BT1, and the other end connected with the corresponding first input terminal TA1. The resistor RA2 has one end connected with the negative electrode of the battery cell BT2, and the other end connected with the first input terminal TA2. The resistor RAn has one end connected with the negative electrode of the battery cell BTn, and the other end connected with the first input terminal TAn. The resistor RA(n+1) has one end connected with the positive electrode of the battery cell BTn, and the other end connected with the first input terminal TA(n+1). Each resistance of the resistors RA1 through RA(n+1) is arbitrarily determined.

The capacitor C1 is connected between the other end of the resistor RA1 and the other end of the resistor RA2. The capacitor Cn is connected between the other end of the resistor RAn and the other end of the resistor RA(n+1).

The resistors RA1 through RA(n+1) and the capacitors C1 through Cn constitute an RC filter to remove unnecessary noise components for voltage measurement.

Each of the cell balance resistors R1 through R(n+1) has one end connected with the positive electrode or the negative electrode of the corresponding battery cell, and the other end connected with the corresponding one of second input terminals T1 through T(n+1) of the voltage monitoring circuit 10. The cell balance resistor R1 has one end connected with the negative electrode of the corresponding battery cell BT1, and the other end connected with the second input terminal T1. The cell balance resistor R(n+1) has one end connected with the positive electrode of the corresponding battery cell BTn, and the other end connected with the second input terminal T(n+1). Each resistance of the cell balance resistors R1 through R(n+1) is arbitrarily determined.

The voltage monitoring circuit 10 includes n cell balance switches SW1 through SWn, n+2 failure detection switches SWA0 through SWA(n+1), a multiplexer 11, a voltage measuring unit 12, a sequencer 13, and an interface 14. The voltage monitoring circuit 10 is a semiconductor integrated circuit, for example. The voltage monitoring circuit 10 may include a control unit 21. In such a case, the voltage monitoring circuit 10 is not required to include the interface 14.

Each of the failure detection switches SWA1 through SWAn is connected between the two first input terminals corresponding to the positive electrode and the negative electrode of the corresponding battery cell. The failure detection switch SWA0 has one end connected with the ground potential and the voltage of the negative electrode of the battery cell BT1, and the other end connected with the input terminal TA1. The failure detection switch SWA(n+1) has one end connected with the input terminal TA(n+1), and the other end connected with the voltage of the positive electrode of the battery cell BTn. The respective failure detection switches SWA0 through SWA(n+1) are controlled by the control unit 21 such that on-off switching of these switches is allowed.

Each of the cell balance switches SW1 through SWn is connected between the two second input terminals corresponding to the positive electrode and the negative electrode of the corresponding battery cell. The respective cell balance switches SW1 through SWn are controlled by the control unit 21 such that on-off switching of these switches is allowed.

The cell balance resistors R1 through R(n+1) and the cell balance switches SW1 through SWn function as a cell balance unit. The cell balance unit supplies current from an arbitrary battery cell to the corresponding two cell balance resistors when an arbitrary cell balance switch is turned on, thereby implementing cell balance for equalizing energies of the respective battery cells.

The multiplexer 11 connects with both ends of each of the failure detection switches SWA1 through SWAn (nodes NA1 through NA(n+1)). The multiplexer 11 selects two nodes from the nodes NA1 through NA(n+1) in accordance with the control by the sequencer 13.

The voltage measuring unit 12 measures the voltage between the two nodes selected by the multiplexer 11, and outputs the measurement result to the interface 14.

The sequencer 13 controls the multiplexer 11 such that two nodes are selected in a predetermined order.

The control unit 21 controls the cell balance switches SW1 through SWn, the failure detection switches SWA0 through SWA(n+1), and the multiplexer 11. The control unit 21 receives the measurement result from the voltage measuring unit 12, and controls an external charge circuit or the like (not shown) and detects disconnection based on the measurement result.

According to this embodiment, the route of the current for cell balance is separated from the route of the voltage measurement. In this arrangement, the voltage measurement is not affected by on-off switching of the cell balance switches SW1 through SWn. In other words, execution of the voltage measurement is allowed regardless of the condition whether each of the cell balance switches SW1 through SWn is on and off.

(Disconnection Detecting Method)

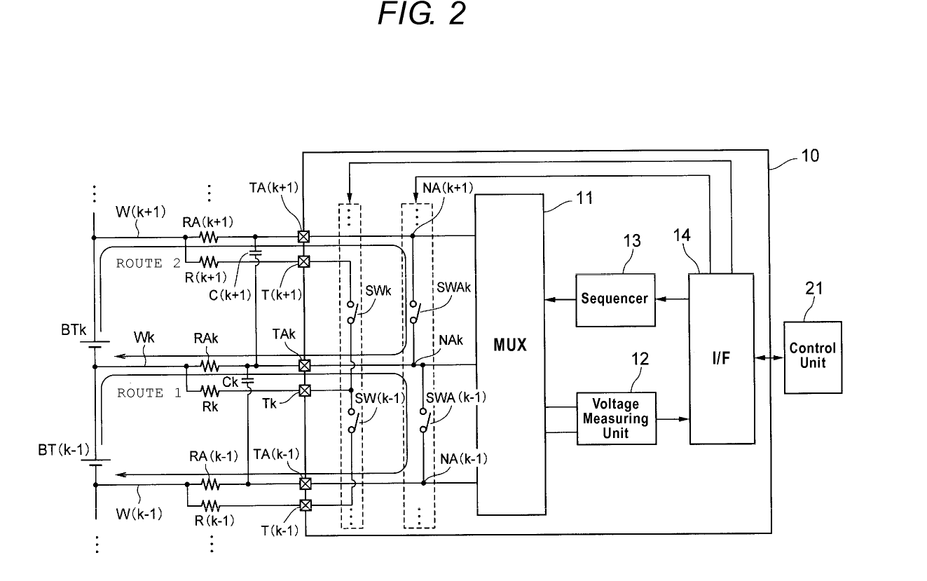

A disconnection detecting method for an assembled battery module is now explained with reference to FIGS. 2 through 5. The term “disconnection” in this context refers to disconnection of wiring which connects the connection nodes between the battery cells and the input terminals TA. FIG. 2 illustrates a disconnection detecting method for an assembled battery module according the first embodiment. More specifically, a disconnection detecting method for a wire Wk (k: arbitrary integer in the range from 2 to n) is discussed. FIG. 2 shows adjoining two battery cells BT(k−1) and BTk, and structures associated with these two battery cells.

The control unit 21 maintains the off condition of the other failure detection switch SWAk of the two failure detection switches SWA(k−1) and SWAk that are commonly connected with the input terminal TAk. In this condition, the control unit 21 measures voltages between the nodes NA(k−1) and NAk and between the nodes NAk and NA(k+1) at the time of on-off switching of the one failure detection switch SWA(k−1). Also, the control unit 21 maintains the off condition of the one failure detection switch SWA(k−1), and measures voltages between the nodes NA(k−1) and NAk and between the nodes NAk and NA(k+1) at the time of on-off switching of the other failure detection switch SWAk. In the following description, it is assumed that each of the voltages between the nodes NA(k−1) and NAk and between the nodes NAk and NA(k+1) at the time of switching of the failure detection switch SWA(k−1) from on to off is a first voltage, and that each of the voltages between the nodes NA(k−1) and NAk and between the nodes NAk and NA(k+1) at the time of switching of the failure detection switch SWAk from on to off is a second voltage.

The control unit 21 maintains the off condition of the other failure detection switch SWAk before and after the switching of the one failure detection switch SWA(k−1) from on to off, and maintains the off condition of the one failure detection switch SWA(k−1) before and after the switching of the other failure detection switch SWAk from on to off.

At the time of detection of failure, the control unit 21 turns off the cell balance switches SW1 through SWn, and also turns off the failure detection switches SWA(k−2) and SWA(k+1) (not shown).

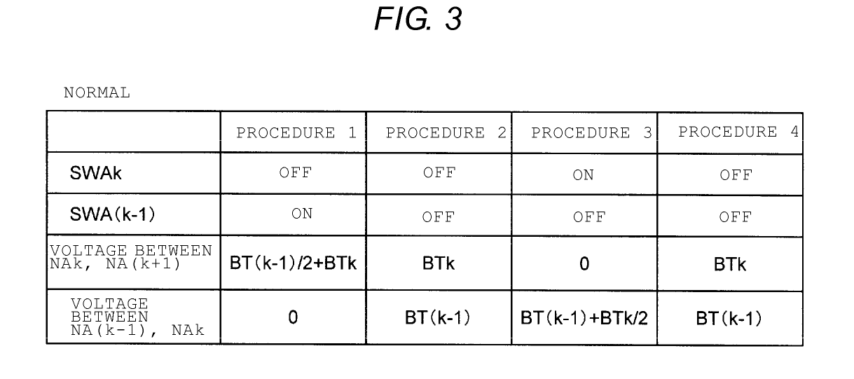

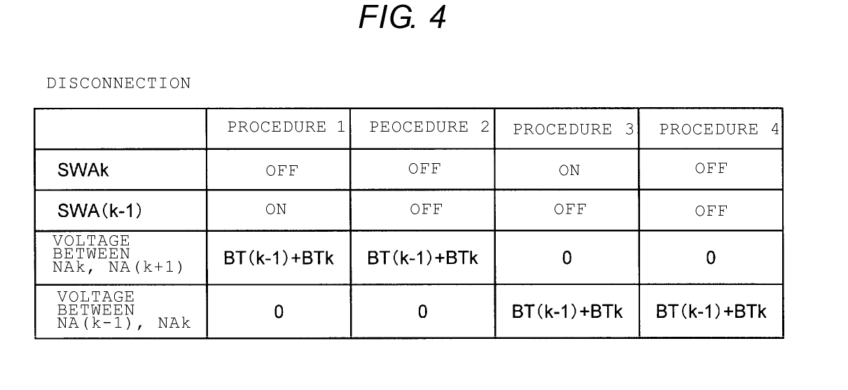

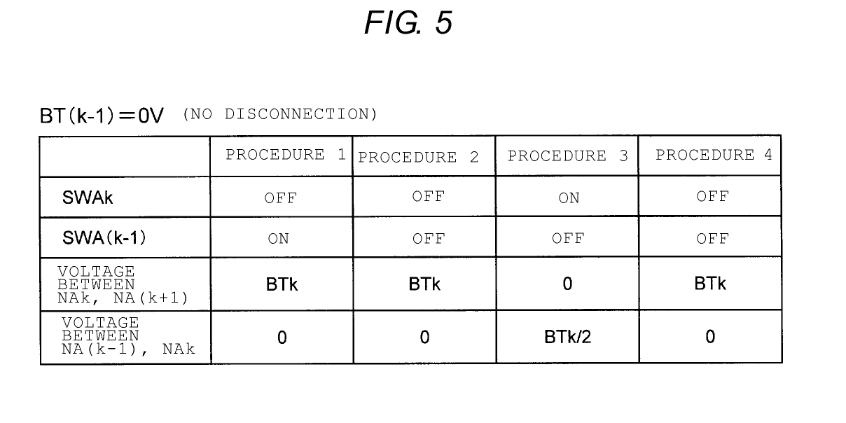

FIG. 3 shows voltages measured in the normal condition. FIG. 4 shows voltages measured in the condition of disconnection. FIG. 5 shows voltages measured when the battery cell BT(k−1) is 0V.

(Procedure 1)

The one failure detection switch SWA(k−1) is turned on, while the other failure detection switch SWAk is turned off. In this case, current flows along a route 1 passing through the battery cell BT(k−1), the resistor RAk, the input terminal TAk, the failure detection switch SWA(k−1), the input terminal TA(k−1), and the resistor RA(k−1) in the normal condition containing no disconnection.

When the ON resistance of the failure detection switch SWA(k−1) is not taken into consideration, the voltages at the nodes NA(k−1) and NAk become equivalent. On the basis of the potential on the negative electrode side of the battery cell BT(k−1), the voltage between the nodes NA(k−1) and the NAk becomes 0V as can be seen from FIG. 3. In this case, the voltage between the nodes NAk and NA(k+1) becomes the sum of the voltage of the battery cell BTk and half the voltage of the battery cell BT(k−1).

On the other hand, no current flows in the condition of disconnection caused in the wire Wk. Therefore, when disconnection occurs, the voltage between the nodes NA(k−1) and NAk becomes 0V as can be seen from FIG. 4. In this case, the voltage between the nodes NAk and NA(k+1) becomes the sum of the voltage of the battery cell BT(k−1) and the voltage of the battery cell BTk.

(Procedure 2)

Subsequently, both the failure detection switches SWA(k−1) and SWAk are turned off.

In the normal condition containing no disconnection, the voltage between the nodes NA(k−1) and NAk becomes the voltage of the battery cell BT(k−1), while the voltage between the nodes NAk and NA(k+1) becomes the voltage of the battery cell BTk.

On the other hand, in the condition of disconnection, the node NAk is in a high-impedance condition. In this case, the voltage immediately before the present condition is maintained by the capacitor of the RC filter or parasitic capacitances generated by the components, wires and the like connected in the neighborhood. More specifically, the voltage at the node NAk is maintained 0V on the basis of the potential on the negative electrode side of the battery cell BT(k−1), in which condition the voltage between the nodes NA(k−1) and NAk becomes 0V. In this case, the voltage between the nodes NAk and NA(k+1) becomes the sum of the voltages of the battery cell BT(k−1) and the battery cell BTk. Thus, occurrence of an abnormality is determined based on the condition in which the voltage between the nodes NA(k−1) and NAk is 0V.

In this condition, however, it is difficult to determine whether the abnormality is caused by the abnormal condition of the battery cell itself without occurrence of disconnection, or by a condition of disconnection. The difficulty in making this determination comes from the fact that 0V is similarly measured as the first voltage between the nodes NA(k−1) and NAk even when the voltage of the battery cell BT(k−1) is 0V without occurrence of disconnection as shown in FIG. 5. For allowing this determination for distinction, the following operation is further continued.

(Procedure 3)

Next, the one failure detection switch SWA(k−1) is turned off, while the other failure detection switch SWAk is turned on. In the normal condition containing no disconnection, current flows along a route 2 passing through the battery cell BTk, the resistor RA(k+1), the input terminal TA(k+1), the failure detection switch SWAk, the input terminal TAk, and the resistor RAk.

When the ON resistance of the failure detection switch SWAk is not taken into consideration, the voltages at the two nodes NAk and NA(k+1) are equivalent. On the basis of the potential on the negative electrode side of the battery cell BT(k−1), the voltage between the nodes NA(k−1) and the NAk becomes the sum of the voltage of the battery cell BT(k−1) and half the voltage of the battery cell BTk as can be seen from FIG. 3. In this case, the voltage between the nodes NAk and NA(k+1) becomes 0V.

On the other hand, no current flows in the condition of disconnection of the wire Wk. Therefore, when disconnection occurs, the voltage between the nodes NAk and NA(k+1) becomes 0V as can be seen from FIG. 4. In this case, the voltage between the nodes NA(k−1) and NAk becomes the sum of the voltage of the battery cell BT(k−1) and the voltage of the battery cell BTk.

(Procedure 4)

Finally, the failure detection switches SWA(k−1) and SWAk are turned off.

In the normal condition containing no disconnection, the voltage between the nodes NA(k−1) and NAk becomes the voltage of the battery cell BT(k−1), while the voltage between the nodes NAk and NA(k+1) becomes the voltage of the battery cell BTk. Thus, these voltages are equivalent to the voltages obtained in the procedure 2.

On the other hand, in the condition of disconnection, the node NAk is in a high-impedance condition. In this case, the voltage immediately before the present condition is maintained by the capacitor of the RC filter or parasitic capacitances generated by the components, wires or the like connected in the neighborhood. More specifically, the voltage at the node NAk is maintained at the sum of the voltages of the battery cell BT(k−1) and the battery cell BTk on the basis of the potential on the negative electrode side of the battery cell BT(k−1). Thus, when the voltage measurement is executed in this condition, the voltage between the nodes NA(k−1) and NAk becomes the sum of the voltages of the battery cell BT(k−1) and the battery cell BTk, while the voltage between the nodes NAk and NA(k+1) becomes 0V.

Accordingly, a measurement result different from the measurement result of the procedure 2 is obtained in the procedure 4 in the case of disconnection. On the other hand, when no disconnection occurs, that is, in the normal condition or in the case of an abnormal condition of the battery cell itself, the measurement result obtained in the procedure 4 is the same as that of the procedure 2. According to this embodiment, therefore, it is allowed to determine whether the abnormality is caused by the abnormal condition of the battery cell itself, or by a disconnection failure.

More specifically, the control unit 21 determines that the node NAk connected with the failure detection switches SWA(k−1) and SWAk is disconnected from the wire Wk connected between the battery cells BT(k−1) and BTk when the first voltage is different from the second voltage.

The control unit 21 determines that the node NAk is not disconnected from the wire Wk connected between the battery cells BT(k−1) and BTk when the first voltage and the second voltage are equivalent.

The control unit 21 determines that failure is caused in the battery cell when the first voltage and the second voltage are both zero.

A method for detecting disconnection of the wires W1 and W(n+1) is now explained.

For disconnection detection of the wire W1, the control unit 21 maintains the off condition of the other failure detection switch SWA1 of the two failure detection switches SWA0 and SWA1 that are commonly connected with the input terminal TA1, and measures the voltage between the nodes NA1 and NA2 at the time of on-off switching of the one failure detection switch SWA0. Also, the control unit 21 maintains the off condition of the one failure detection switch SWA0, and measures the voltage between the nodes NA1 and NA2 at the time of on-off switching of the other failure detection switch SWA1. In the following description, it is assumed that the voltage between the nodes NA1 and NA2 at the time of switching of the failure detection switch SWA0 from on to off is a first voltage, and that the voltage between the nodes NA1 and the NA2 at the time of switching of the failure detection switch SWA1 from on to off is a second voltage.

(Procedure 1)

The failure detection switch SWA0 is turned on, while the failure detection switch SWA1 is turned off. In this case, the voltage at the node NA1 becomes the voltage of the negative electrode of the battery cell BT1 (ground voltage) both in the normal condition containing no disconnection and in the condition of disconnection. Thus, the voltage between the nodes NA1 and NA2 is equivalent to the voltage of the battery cell BT1.

(Procedure 2)

Subsequently, both the failure detection switches SWA0 and SWA1 are turned off.

In the normal condition containing no disconnection, the first voltage between the nodes NA1 and NA2 becomes the voltage of the battery cell BT1.

On the other hand, in the condition of disconnection, the voltage at the node NA1 having a high impedance is equivalent to the voltage of the negative electrode of the battery cell BT1 continuously from the procedure 1. Thus, the first voltage between the nodes NA1 and NA2 becomes the voltage of the battery cell BT1.

(Procedure 3)

Then, the failure detection switch SWA0 is turned off, while the failure detection switch SWA1 is turned on. In this case, the voltage between the nodes NA1 and NA2 in the on condition becomes 0V both in the normal condition containing no disconnection and in the condition of disconnection.

(Procedure 4)

Finally, the failure detection switches SWA0 and SWA1 are turned off.

In the normal condition containing no disconnection, the second voltage between the nodes NA1 and NA2 becomes the voltage of the battery cell BT1. Thus, the second voltage is equivalent to the first voltage obtained in the procedure 2.

On the other hand, in the condition of disconnection, the voltage at the node NA1 having a high impedance is equivalent to the voltage at the node NA2 continuously from the procedure 3. In this case, the second voltage between the nodes NA1 and NA2 becomes 0V. Thus, the second voltage is different from the first voltage obtained in the procedure 2.

Accordingly, the control unit 21 determines that the wire W1 connected between the node NA1 and the negative electrode of the battery cell BT1 is disconnected when the first voltage is different from the second voltage.

The control unit 21 determines that the wire W1 connected between the node NA1 and the negative electrode of the battery cell BT1 is not disconnected when the first voltage and the second voltage are equivalent.

The control unit 21 determines that failure is caused in the battery cell B1 when the first voltage and the second voltage are both zero.

As for detection of disconnection of the wire W(n+1), the control unit 21 maintains the off condition of the other failure detection switch SWAn of the two failure detection switches SWAn and SWA(n+1) that are commonly connected with the input terminal TA(n+1), and measures the voltage between the nodes NAn and NA(n+1) at the time of on-off switching of the one failure detection switch SWA(n+1). Also, the control unit 21 maintains the off condition of the one failure detection switch SWA(n+1), and measures the voltage between the nodes NAn and NA(n+1) at the time of on-off switching of the other failure detection switch SWAn. In the following description, it is assumed that the voltage between the nodes NAn and NA(n+1) at the time of switching of the failure detection switch SWA(n+1) from on to off is a first voltage, and the voltage between the nodes NAn and NA(n+1) at the time of switching of the failure detection switch SWAn from on to off is a second voltage.

(Procedure 1)

The failure detection switch SWA(n+1) is turned on, while the failure detection switch SWAn is turned off. In this case, the voltage at the node NA(n+1) becomes the voltage of the positive electrode of the battery cell BTn (power source voltage) both in the normal condition containing no disconnection and in the condition of disconnection. Thus, the voltage between the nodes NAn and NA(n+1) is equivalent to the voltage of the battery cell BTn.

(Procedure 2)

Subsequently, both the failure detection switches SWAn and SWA(n+1) are turned off.

In the normal condition containing no disconnection, the first voltage between the nodes NAn and NA(n+1) becomes the voltage of the battery cell BTn.

On the other hand, in the condition of disconnection, the voltage at the node NA(n+1) having a high impedance is equivalent to the voltage of the positive electrode of the battery cell BTn continuously from the procedure 1. Thus, the first voltage between the nodes NAn and NA(n+1) becomes the voltage of the battery cell BTn.

(Procedure 3)

Then, the failure detection switch SWA(n+1) is turned off, while the failure detection switch SWAn is turned on. In this case, the voltage between the nodes NAn and NA(n+1) in the on condition becomes 0V both in the normal condition containing no disconnection and in the condition of disconnection.

(Procedure 4)

Finally, the failure detection switches SWAn and SWA(n+1) are turned off.

In the normal condition containing no disconnection, the second voltage between the nodes NAn and NA(n+1) becomes the voltage of the battery cell BTn. Thus, the second voltage is equivalent to the first voltage obtained in the procedure 2.

On the other hand, in the condition of disconnection, the voltage at the node NA(n+1) having a high impedance is equivalent to the voltage at the node NAn continuously from the procedure 3. In this case, the second voltage between the nodes NAn and NA(n+1) becomes 0V. Thus, the second voltage is different from the first voltage obtained in the procedure 2.

Accordingly, the control unit 21 determines that the wire W(n+1) connected between the node NA(n+1) and the positive electrode of the battery cell BTn is disconnected when the first voltage is different from the second voltage.

The control unit 21 determines that the wire W(n+1) connected between the node NAn and the positive electrode of the battery cell BTn is not disconnected when the first voltage and the second voltage are equivalent.

The control unit 21 determines that failure is caused in the battery cell BTn when the first voltage and the second voltage are both zero.

Disconnection of the wire W is detected by executing the procedures 1 through 4 for the two failure detection switches SWA connected to the wire W. The order of execution of these procedures may be switched. That is, similar disconnection detection may be achieved even when the procedures are executed in the order of 3, 4, 1, and 2.

Disconnection detection may be performed either at the time of the step for turning on the power source, or on a regular basis. Alternatively, disconnection detection may be performed on the occasion when the measured voltage of a certain battery cell is 0V so as to clarify whether this measurement comes from disconnection or from the condition in which the voltage of the corresponding battery cell is 0V.

According to this embodiment, therefore, the failure detection switches SWA0 through SWA(n+1) are provided, and disconnection is determined based on the first voltage and the second voltage measured by on-off control of the failure detection switches SWA(k−1) and SWAk connected with the node NAk as a common node for these switches.

In this case, disconnection is determined when the first voltage is different from the second voltage. Accordingly, highly accurate disconnection detection is allowed regardless of the normal condition or the abnormal condition of the battery cells BT(k−1) and BTk.

The control unit 21 may be configured to control a not-shown charge circuit or the like at the time of detection of disconnection in such a manner as to stop charging of the battery cells BT1 through BTn after the detection of disconnection. This structure avoids excessive charging of the battery cell whose voltage is difficult to measure due to disconnection.

### Modified Example of First Embodiment

According to the structure including a plurality of pairs of the failure detection switches each pair of which are connected to one common node for the corresponding switches, the procedures 1 through 4 may be executed for each pair in parallel with execution of these procedures for other pairs. In this case, at least one failure detection switch maintaining the off condition during the procedures 1 through 4 may be equipped at a position between two adjoining failure detection switches connected to a certain common node and two adjoining failure detection switches connected to another common node.

According to the structure including a plurality of pairs of the failure detection switches each pair of which are connected to one common node for the corresponding switches, the procedures 1 through 4 may be executed for each pair in parallel with execution of these procedures for other pairs such that the failure detection switches SWA0 through SWA(n+1) are alternately turned on for each of the procedures 1 through 3. More specifically, among the failure detection switches SWA0 through SWA(n+1), two switches connected to the same node are not simultaneously turned on in the procedure 1 and the procedure 3. For example, during the procedure 1, assuming that n is an even number, the failure detection switch SWA0 and the even number failure detection switches SWA2, SWA4, through SWA(n−2), up to SWAn are turned on, while the other odd number failure detection switches SWA1, SWA3, through SWA(n−1), up to SWA(n+1) are turned off, in which condition the respective voltages between the adjoining nodes are measured. Then, during the procedure 2, all the failure detection switches SWA0 through SWA(n+1) are turned off, and the respective voltages between the adjoining nodes are measured. Subsequently, during the procedure 3, the failure detection switch SWA0 and the even number failure detection switches SWA2, SWA4, through SWA(n−2), up to SWAn are turned off, while the other odd number failure detection switches SWA1, SWA3, through SWA(n−1), up to SWA(n+1) are turned on, in which condition the respective voltages between the adjoining nodes are measured. Finally, during the procedure 4, all the failure detection switches SWA0 through SWA(n+1) are turned off, and the voltages between the adjoining nodes are measured.

In these modified examples, advantages similar to those of the first embodiment are offered. According to at least one of the embodiments described herein, disconnection is detected with high accuracy by using the failure detection switches SWA0 through SWA(n+1) provided for the respective embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An assembled battery module, comprising:
a plurality of battery cells connected in series;
a plurality of resistors each of which is connected between a positive or negative electrode of a corresponding battery cell, and a corresponding node for the positive or negative electrode;
a multiplexer configured to select two nodes corresponding to the positive electrode and the negative electrode of any one of the battery cells;
a voltage measuring unit configured to measure the voltage between the two nodes selected by the multiplexer;
a plurality of failure detection switches each of which is connected between two nodes corresponding to the positive electrode and the negative electrode of one of the battery cells to allow on-off switching between the two nodes;
a control unit configured to detect a disconnection between a positive or negative electrode of one of the battery cells and a corresponding node for the positive or negative electrode based on first and second voltages measured between the corresponding node and either a first node that is connected to the corresponding node through a first failure detection switch or a second node that is connected to the corresponding node through a second failure detection switch, the first voltage being measured when the second failure detection switch is switched from on to off and the second voltage being measured when the first failure detection switch is switched from on to off.

2. The module according to claim 1, wherein the disconnection is detected if the first and second voltages are different.

3. The module according to claim 2, wherein the disconnection is not detected if the first and second voltages are the same.

4. The module according to claim 3, wherein an abnormal condition is detected in the battery cell having a positive electrode connected to the corresponding node through one of the resistors if the first voltage is the same before and after the second failure detection switch is switched from on to off or the second voltage is the same before and after the first failure detection switch is switched from on to off.

5. The module according to claim 1, wherein
the control unit maintains the first failure detection switch off before and after switching of the second failure detection switch from on to off, and maintains the second failure detection switch off before and after switching of the first failure detection switch from on to off.

6. The module according to claim 1, wherein the plurality of battery cells include a first battery cell having a negative electrode connected to a first node through a first resistor and a positive electrode connected to a second node through a second resistor, and a second battery cell having a negative electrode connected to the positive electrode of the first battery cell and the second node and a positive electrode connected to a third node through a third resistor.

7. The module according to claim 6, wherein the second node is the corresponding node.

8. An assembled battery module, comprising:
a plurality of battery cells, including a first battery cell and a second battery cell connected in series such that a positive electrode of the first battery cell is connected to a negative electrode of the second battery cell;
a first resistor connected between a negative electrode of the first battery cell and a first node;
a second resistor connected between a negative electrode of the second battery cell and a second node;
a third resistor connected between a positive electrode of the second battery cell and a third node;
a voltage measuring unit configured to measure the voltage between the first and second nodes and between the second and third nodes;
a first failure detection switch connected between the first and second nodes;
a second failure detection switch connected between the second and third nodes; and
a control unit configured to detect a disconnection between a negative electrode of the second battery cell and the second node based on first and second voltages measured between the second node and another node, the first voltage being measured when the second failure detection switch is switched from on to off and the second voltage being measured when the first failure detection switch is switched from on to off.

9. The module according to claim 8, wherein said another node is the first node.

10. The module according to claim 8, wherein said another node is the third node.

11. The module according to claim 8, wherein the disconnection is detected if the first and second voltages are different.

12. The module according to claim 11, wherein the disconnection is not detected if the first and second voltages are the same.

13. The module according to claim 12, wherein an abnormal condition is detected in the second battery cell if the first voltage is the same before and after the second failure detection switch is switched from on to off or the second voltage is the same before and after the first failure detection switch is switched from on to off.

14. The module according to claim 8, wherein
the control unit maintains the first failure detection switch off before and after switching of the second failure detection switch from on to off, and maintains the second failure detection switch off before and after switching of the first failure detection switch from on to off.

15. In an assembled battery module comprising:
a plurality of battery cells, including a first battery cell and a second battery cell connected in series such that a positive electrode of the first battery cell is connected to a negative electrode of the second battery cell;
a first resistor connected between a negative electrode of the first battery cell and a first node;
a second resistor connected between a negative electrode of the second battery cell and a second node;
a third resistor connected between a positive electrode of the second battery cell and a third node;
a voltage measuring unit configured to measure the voltage between the first and second nodes and between the second and third nodes;
a first failure detection switch connected between the first and second nodes; and
a second failure detection switch connected between the second and third nodes,
a method of detecting a disconnection between a negative electrode of the second battery cell and the second node, comprising:
measuring a first voltage between the second node and another node when the second failure detection switch is switched from on to off;
measuring a second voltage between the second node and another node when the first failure detection switch is switched from on to off; and
detecting the disconnection based on the first and second voltages.

16. The method according to claim 15, wherein the first failure detection switch is maintained off before and after switching of the second failure detection switch from on to off, and the second failure detection switch is maintained off before and after switching of the first failure detection switch from on to off.

17. The method according to claim 15, wherein the disconnection is detected if the first and second voltages are different.

18. The method according to claim 17, wherein the disconnection is not detected if the first and second voltages are the same.

19. The method according to claim 15, further comprising:
detecting an abnormal condition in the second battery cell if the first voltage is the same before and after the second failure detection switch is switched from on to off or the second voltage is the same before and after the first failure detection switch is switched from on to off.

20. The method according to claim 8, wherein said another node is one of the first node and the third node.
